(19) United States
(12) Patent Application Publication
(10) Pub. No.: US 2013/0037107 A1
(43) Pub. Date: Feb. 14, 2013

(54) ADHESIVE LAYER FOR PHOTOVOLTAIC MODULE

(71) Applicants: Stephen Yau Sang CHENG, New Territories (HK); Yen Chih-He, Tsuen Wan (HK)

(72) Inventors: Stephen Yau Sang CHENG, New Territories (HK); Yen Chih-He, Tsuen Wan (HK)

(73) Assignee: DU PONT APOLLO LTD., New Territories (HK)

(21) Appl. No.: 13/205,073

(22) Filed: Aug. 8, 2011

(51) Int. Cl. H01L 31/0203; H01L 31/18

(52) U.S. Cl. 136/259; 438/57; 257/E31.117

(57) ABSTRACT

A photovoltaic (PV) module comprising a pressure sensitive adhesive to attach solar cells and a dielectric layer to each other has been disclosed. The use of the pressure sensitive adhesive in the photovoltaic module can significantly simplify the module assembly process.

### FIELD OF THE INVENTION

The present invention relates to the field of photovoltaic (PV) modules, particularly to the use of a pressure sensitive adhesive (PSA) therein so as to significantly simplify the photovoltaic module assembly process.

### BACKGROUND OF THE INVENTION

Generally, a photovoltaic (PV) module is a semiconductor device capable of converting light energy, particularly solar energy, into electric energy through the photoelectric effect. There are two major types of solar cells commonly used in photovoltaic modules, one comprising silicon and the other comprising thin film. Silicon type is currently the predominant technology, and can generally be implemented as monocrystalline or polycrystalline solar cells which are encapsulated behind a transparent glass front plate to form crystalline silicon photovoltaic modules with good module efficiency. Thin film technology is not as wide-spread as silicon technology due to its reduced efficiency, but it is gaining popularity due to its potentially lower cost.

Current thin-film PV modules utilize materials traditionally used for crystalline silicon photovoltaic modules. A conventional photovoltaic module mainly comprises a glass substrate (or some other transparent materials) to allow light to pass through, solar cell(s), and an encapsulant film, such as ethylene vinyl acetate (EVA) or polyvinyl butyral (PVB), to bond the glass substrate with a backsheet. The backsheet is normally a multilayered laminate, comprising an electrically insulating layer such as a biaxially oriented polyethylene terephthalate (BO-PET) sheet, which provides dimensional stability and electrical insulation, and a weather protective layer, which can be made of fluoropolymers such as polyvinyl fluoride (PVF) and polyvinylidene fluoride (PVDF). An additional barrier layer, such as aluminum foil, is required for the thin-film photovoltaic module due to the higher sensitivity of the modules to moisture compared with the crystalline silicon photovoltaic modules.

EVA and PVB are hot melt adhesives. They are not tacky at normal temperatures, and become sticky when molten and harden when cooled from the molten state in a few seconds to tens of minutes. In the case of EVA, typically the composition undergoes a crosslinking step in order to prevent the encapsulant film from creep at high operating or environmental temperatures. Since the photovoltaic module is a laminated stack, the process of assembling the module with EVA or PVB encapsulant is inconvenient and time-consuming.

Therefore, the basic design and the assembly process of photovoltaic modules are complex and have drawbacks. The applicant intends to look for an adhesive to replace the EVA or PVB encapsulant. Moreover, to ensure reliability of the thin-film photovoltaic modules and avoid short circuiting due to the presence of an aluminum foil in the backsheet, a certain thickness of the dielectric material needs to be present between the solar cells and the aluminum foil. Typically, the thickness of the BO-PET sheet used in the backsheet is at least 150 to 250 microns. Combined with the typical thickness of the EVA encapsulant of 400 to 600 microns, the total thickness exceeds 600 microns. However, the biaxial orientation process for making the BO-PET sheet of thicknesses greater than 100 microns requires a higher level of technical know-how to ensure that the product has the desire properties, such as consistent and uniform thickness, which at the moment allows manufacturers with such know-how to command a price premium and which as a result adds directly to the cost of a backsheet.

Thus, there is a need in developing an improved photovoltaic module with simplified assembly.

### SUMMARY OF THE INVENTION

In view of the problems described above, the present invention provides an improved photovoltaic (PV) module which uses a pressure sensitive adhesive to replace conventional EVA or PVB encapsulant so that a module assembly process can be significantly simplified.

According to the present invention, the photovoltaic module comprises a transparent substrate, at least one solar cell, and a backsheet comprising a dielectric layer sequentially stacked, characterized in that a pressure sensitive adhesive is disposed between the solar cell and the dielectric layer to attach them to each other.

The present invention further provides a method of making a photovoltaic module, comprising providing a transparent substrate, providing at least one solar cell on the transparent substrate, providing a pressure sensitive adhesive on the solar cell, and providing a backsheet comprising a dielectric layer on the pressure sensitive adhesive. According to the present invention, the pressure sensitive adhesive is used to replace conventional EVA or PVB encapsulant to adhere the solar cell(s) and the dielectric layer.

### BRIEF DESCRIPTION OF THE DRAWING

FIG. 1 shows a schematic cross-sectional view of a conventional thin-film photovoltaic module.

FIG. 2 shows a schematic cross-sectional view of a thin-film photovoltaic module according to an embodiment of the present invention.

FIG. 3 shows a schematic cross-sectional view of a conventional crystalline silicon photovoltaic module.

FIG. 4 shows a schematic cross-sectional view of a crystalline silicon photovoltaic module according to an embodiment of the present invention.

### DETAILED DESCRIPTION OF THE INVENTION

For better understanding, the present invention is illustrated below in detail by the embodiments with reference to the drawings, which are not intended to limit the scope of the present invention. It will be apparent that any modifications or alterations that can easily be accomplished by those having ordinary skill in the art fall within the scope of the disclosure of the specification.

According to the present invention, the photovoltaic module is a thin-film photovoltaic module or a crystalline silicon photovoltaic module.

### First Embodiment

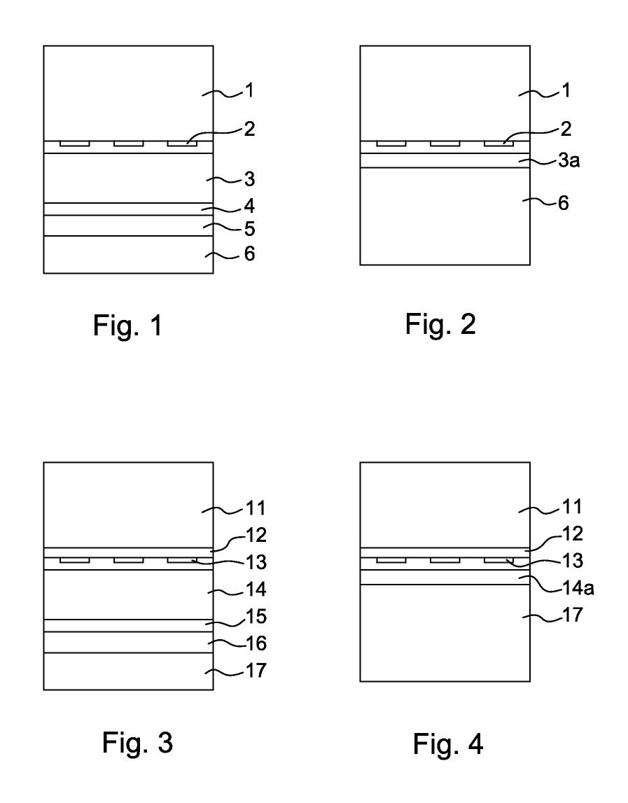

FIG. 1 shows a schematic cross-sectional view of a conventional thin-film photovoltaic module. As shown in FIG. 1, a conventional thin-film photovoltaic module mainly comprises a transparent superstrate 1 (such as glass and plastic), thin-film solar cells 2, an encapsulant 3 (such as EVA and PVB), and a backsheet including a tie layer 4, an adhesive layer 5, and a dielectric layer 6 (such as biaxially oriented polyethylene terephthalate (BO-PET)) sequentially stacked. The purpose of the tie layer 4 is to enable the adhesion of the dielectric layer 6 to the encapsulant 3 of the photovoltaic module. The tie layer 4 is usually composed of a polymer of EVA of vinylacetate comonomer content of around 4-8%, which has compatibility with the EVA polymer in the encapsulant 3 to effect bonding. It is also known that some manufacturers use linear low-density polyethylene (LLDPE) as the tie layer material. The adhesive layer 5 can be any type or form of adhesive which enables the bonding of the two layers, and comprises, but is not limited to, two-part polyurethane adhesives.

FIG. 2 shows a schematic cross-sectional view of a thin-film photovoltaic module according to an embodiment of the present invention. As shown in FIG. 2, the present invention uses a pressure sensitive adhesive (PSA) 3a to replace the conventional EVA or PVB encapsulant 3 as depicted in FIG. 1. Pressure sensitive adhesive is an adhesive which forms a bond when pressure is applied to marry the adhesive with the adherend. No solvent, water, or heat is needed to activate the adhesive. Due to the use of the pressure sensitive adhesive in the thin-film photovoltaic module to adhere the thin-film solar cells 2 to the dielectric layer 6, the tie layer 4 and the adhesive layer 5 depicted in FIG. 1 can be avoided, and thus the process of assembling the thin-film photovoltaic module can be significantly simplified.

The pressure sensitive adhesive suitable for use in the present invention comprises, but is not limited to, a silicone-based pressure sensitive adhesive, a rubber-based pressure sensitive adhesive, an acrylic pressure sensitive adhesive, an epoxy pressure sensitive adhesive, or an urethane pressure sensitive adhesive. Permanent pressure sensitive adhesives can also be used, where a curing step can take place to further strengthen the bond. The curing may require heat or can take place at room temperature over time. Examples of commercially available adhesives which can be used in the present invention include, but are not limited to, Dow Corning 7659 (a silicon-based pressure sensitive adhesive), 3M Permanent Pressure Sensitive Adhesive P1212 and Henkel's Durotak 80-1057 (acrylic pressure sensitive adhesives). According to an embodiment of the present invention, the thickness of the pressure sensitive adhesive is less than 500 microns, preferably less than 300 microns, and more preferably less than 100 microns.

According to the present invention, the dielectric layer is made of a material which can bond well to the pressure sensitive adhesive. To ensure reliability of thin-film photovoltaic modules, the dielectric layer is preferably a foam dielectric layer or a fibrous dielectric layer which provides an additional surface area for bonding. The form or fibrous dielectric layer is of a suitable thickness to provide adequate electrical insulation. Preferably, the dielectric layer has a greater thickness than conventional dielectric layers. According to an embodiment of the present invention, the thickness of the dielectric layer is more than 100 microns, preferably more than 300 microns, and more preferably more than 500 microns. The foam dielectric or fibrous layer suitable for use in the present invention can be made from any suitable electrically insulating materials, such as but not limited to polyolefin foams or sheets made from polymer fibers such as PET. According to an embodiment of the present invention, the foam dielectric layer is made from polyethylene, polyethylene copolymers, polypropylene, natural rubbers, or synthetic rubbers, and the fibrous dielectric layer is made from various synthetic fibers such as polyethylene, polypropylene, PET, and nylon, or various natural fibers such as cellulosic fibers, for example those found in paper.

According to the present invention, the transparent superstrate suitable for use in a thin-film photovoltaic module is known to persons having ordinary skill in the art, and typically comprises a glass or plastic substrate and a transparent conductive oxide (TCO) layer.

According to an embodiment of the present invention, the backsheet further comprises a barrier layer and a weather protective layer (not shown). According to an embodiment of the present invention, the barrier layer and the weather protective layer are sequentially stacked on the dielectric layer, and can be bonded together directly (for example, using a co-extrusion or extrusion coating process) or via adhesives. Such adhesives can be solvent-based, water-based or hot melt forms.

The barrier layer suitable for use in the present invention is obvious to persons having ordinary skill in the art, and can be made of any suitable materials, such as metallic materials, polymeric materials, inorganic materials, and a combination thereof. Aluminum barrier layer is preferred. According to the present invention, the thickness of the barrier layer is preferably at least 1 micron, more preferably at least 10 microns, and most preferably at least 25 microns.

The weather protective layer suitable for use in the present invention is obvious to persons having ordinary skill in the art, and can be made of any suitable materials, such as metallic materials, polymeric materials, inorganic materials, and a combination thereof. According to the present invention, the thickness of the weather protective layer is preferably at least 1 micron, more preferably at least 10 microns, and most preferably at least 25 microns.

### Second Embodiment

FIG. 3 shows a schematic cross-sectional view of a conventional crystalline silicon photovoltaic module. As shown in FIG. 3, a conventional crystalline silicon photovoltaic module mainly comprises a transparent substrate 11 (such as glass and plastic), an encapsulant 12 (such as EVA and PVB), crystalline silicon solar cells 13, an encapsulant 14 (such as EVA and PVB), and a backsheet including a tie layer 15, an adhesive layer 16, and a dielectric layer 17 (such as biaxially oriented polyethylene terephthalate (BO-PET)) sequentially stacked.

FIG. 4 shows a schematic cross-sectional view of a crystalline silicon photovoltaic module according to an embodiment of the present invention. As shown in FIG. 4, the present invention uses a pressure sensitive adhesive (PSA) 14a to replace the conventional EVA or PVB encapsulant 14. Due to the use of the pressure sensitive adhesive in the crystalline silicon photovoltaic module to adhere the crystalline silicon solar cells 13 to the dielectric layer 17, the tie layer 15 and the adhesive layer 16 depicted in FIG. 3 can be avoided, and thus the process of assembling the crystalline silicon photovoltaic module can be significantly simplified. The pressure sensitive adhesive suitable for use in the present invention has been disclosed in the first embodiment.

The dielectric layer 17 can be made from any suitable electrically insulating materials, such as but not limited to PET, and preferably has a thickness of at least 50 microns, more preferably at least 100 microns, and most preferably at least 200 microns. According to an embodiment of the present invention, the dielectric layer 17 can be a foam dielectric layer or a fibrous dielectric layer as disclosed in the first embodiment.

According to the present invention, the transparent substrate suitable for use in a crystalline silicon photovoltaic module is known to persons having ordinary skill in the art, for example, but not limited to, glass or plastic.

According to an embodiment of the present invention, the backsheet further comprises a weather protective layer (not shown) stacked on the dielectric layer. The weather protective layer suitable for use in the present invention has been disclosed in the first embodiment.

The main benefit of using a pressure sensitive adhesive to replace EVA or PVB encapsulant is that it requires little or no heat for the lamination to take place. Since bonding with the pressure sensitive adhesive is immediate, it takes little time to laminate EVA or PVB encapsulant and curing of EVA or PVB encapsulant is unnecessary after lamination. Thus, the process of assembling the photovoltaic module can be significantly simplified.

As shown in Table 1, the characteristics of the photovoltaic modules of Example 1 are similar to those of Comparative Example 1. Therefore, the use of PSA adhesives not only creates a photovoltaic module with equivalent functionality to one using conventional EVA encapsulation techniques, but also significantly simplifies the photovoltaic module assembly process.

Although the present invention has been described with reference to illustrative embodiments, it should be understood that any modifications or alterations that can easily be accomplished by persons skilled in the art will fall within the scope of the disclosure of the specification and the appended claims.

What is claimed is:

1. A photovoltaic (PV) module comprising a transparent substrate, at least one solar cell, and a backsheet comprising a dielectric layer sequentially stacked, characterized in that a pressure sensitive adhesive is disposed between the solar cell and the dielectric layer to attach them to each other.

2. The photovoltaic module of claim 1, wherein the pressure sensitive adhesive is selected from the group consisting of a silicone-based pressure sensitive adhesive, a rubber-based pressure sensitive adhesive, an acrylic pressure sensitive adhesive, an epoxy pressure sensitive adhesive, and an urethane pressure sensitive adhesive.

3. The photovoltaic module of claim 1, wherein the pressure sensitive adhesive has a thickness of less than about 300 microns.

4. The photovoltaic module of claim 3, wherein the pressure sensitive adhesive has a thickness of less than about 100 microns.

5. The photovoltaic module of claim 1, wherein the photovoltaic module is a thin-film photovoltaic module.

6. The photovoltaic module of claim 5, wherein the transparent substrate comprises a glass superstrate or a plastic superstarte.

7. The photovoltaic module of claim 5, wherein the dielectric layer is selected from the group consisting of a foam dielectric layer and a fibrous dielectric layer.

8. The photovoltaic module of claim 7, wherein the foam dielectric layer is selected from the group consisting of polyethylene, polyethylene copolymers, polypropylene, natural rubbers, and synthetic rubbers.

9. The photovoltaic module of claim 7, wherein the fiber dielectric layer is selected from the group consisting of polyethylene, polypropylene, polyethylene terephthalate, nylon, and cellulosic fibers.

10. The photovoltaic module of claim 5, wherein the dielectric layer has a thickness of more than about 300 microns.

11. The photovoltaic module of claim 10, wherein the dielectric layer has a thickness of more than about 500 microns.

12. The photovoltaic module of claim 5, wherein the backsheet further comprises a barrier layer and a weather protective layer sequentially stacked on the dielectric layer.

13. The photovoltaic module of claim 1, wherein the photovoltaic module is a crystalline silicon photovoltaic module.

14. The photovoltaic module of claim 13, wherein the transparent substrate comprises a glass substrate or a plastic substrate.

15. The photovoltaic module of claim 13, wherein the dielectric layer is selected from the group consisting of a foam dielectric layer and a fibrous dielectric layer.

16. The photovoltaic module of claim 15, wherein the foam dielectric layer is selected from the group consisting of polyethylene, polyethylene copolymers, polypropylene, natural rubbers, and synthetic rubbers.

17. The photovoltaic module of claim 15, wherein the fiber dielectric layer is selected from the group consisting of polyethylene, polypropylene, polyethylene terephthalate, nylon, and cellulosic fibers.

18. The photovoltaic module of claim 13, wherein the dielectric layer has a thickness of more than about 100 microns.

19. The photovoltaic module of claim 13, wherein the backsheet further comprises a weather protective layer stacked on the dielectric layer.

20. A method of making a photovoltaic module, comprising providing a transparent substrate, providing at least one solar cell on the transparent substrate, providing a pressure sensitive adhesive on the solar cell, and providing a backsheet comprising a dielectric layer on the pressure sensitive adhesive.
